(19) United States
(12) Patent Application Publication
(10) Pub. No.: US 2024/0315120 A1
(43) Pub. Date: Sep. 19, 2024

(54) MANUFACTURING DEVICE OF DISPLAY DEVICE

(71) Applicant: Japan Display Inc., Tokyo (JP)

(72) Inventor: Shigeki TERADA, Tokyo (JP)

(73) Assignee: Japan Display Inc., Tokyo (JP)

(21) Appl. No.: 18/585,091

(22) Filed: Feb. 23, 2024

(30) Foreign Application Priority Data
Mar. 17, 2023 (JP) 2023-043189

(51) Int. Cl. H10K 71/16

(52) U.S. Cl. CPC H10K 71/164

(57) ABSTRACT

According to one embodiment, a manufacturing device of a display device includes a vacuum chamber, a conveyance path provided inside the vacuum chamber and provided for conveying a processing substrate for the display device, and an ionizer provided such that ions are generated inside the vacuum chamber. The ionizer includes a sub-chamber accommodated in the vacuum chamber and including a hole, a gas supply portion which supplies an inactive gas to the sub-chamber, and an irradiation source which applies vacuum ultraviolet rays or X-rays for ionizing the inactive gas supplied to inside of the sub-chamber.

### CROSS-REFERENCE TO RELATED APPLICATIONS

This application is based upon and claims the benefit of priority from Japanese Patent Application No. 2023-043189, filed Mar. 17, 2023, the entire contents of which are incorporated herein by reference.

### FIELD

Embodiments described herein relate generally to a manufacturing device of a display device.

### BACKGROUND

Recently, display devices to which an organic light emitting diode (OLED) is applied as a display element have been put into practical use. This display element comprises a pixel circuit including a thin-film transistor, a lower electrode connected to the pixel circuit, an organic layer which covers the lower electrode, and an upper electrode which covers the organic layer. The organic layer includes functional layers such as a hole transport layer and an electron transport layer in addition to a light emitting layer.

In the process of manufacturing such a display element, a technique which prevents the reduction in reliability and yield has been required.

### BRIEF DESCRIPTION OF THE DRAWINGS

FIG. 1 is a diagram showing a configuration example of a display device DSP.

FIG. 2 is a diagram showing an example of the layout of subpixels SP1, SP2 and SP3.

FIG. 3 is a schematic cross-sectional view of the display device DSP along the A-B line of FIG. 2.

FIG. 4 is a diagram showing a configuration example of a display element 20.

FIG. 5 is a diagram showing a configuration example of a manufacturing device 100.

FIG. 6 is a cross-sectional view showing a configuration example of a typical evaporation chamber EV11.

FIG. 7 is a diagram for explaining an ionizer 200 which can be applied to the manufacturing device 100 shown in FIG. 5.

FIG. 8 is a diagram for explaining an installation example of the ionizer 200 in the manufacturing device 100 shown in FIG. 5.

### DETAILED DESCRIPTION

Embodiments described herein aim to provide a manufacturing device of a display device such that the reduction in reliability and yield can be prevented.

In general, according to one embodiment, a manufacturing device of a display device comprises a vacuum chamber, a conveyance path provided inside the vacuum chamber and provided for conveying a processing substrate for the display device, and an ionizer configured to generate ions inside the vacuum chamber. The ionizer comprises a sub-chamber accommodated in the vacuum chamber and comprising a hole, a gas supply portion configured to supply an inactive gas to the sub-chamber, and an irradiation source configured to apply vacuum ultraviolet rays or X-rays for ionizing the inactive gas supplied to inside of the sub-chamber.

According to yet another embodiment, a manufacturing device of a display device comprises a substrate compartment which accommodates a processing substrate for the display device in which a lower electrode is formed, a preprocessing portion which performs a preprocess for the processing substrate, an evaporation chamber comprising an evaporation source configured to emit a material for forming one of an organic layer, an upper electrode and a cap layer toward the processing substrate, a conveyance chamber in which the processing substrate is conveyed, a rotation chamber comprising a rotation mechanism configured to rotate while holding the processing substrate, a post-processing portion which performs a post-process for the processing substrate, and an ionizer provided in at least one vacuum chamber of the substrate compartment, the preprocessing portion, the evaporation chamber, the conveyance chamber, the rotation chamber and the post-processing portion, and configured to generate ions inside the vacuum chamber. The ionizer comprises a sub-chamber accommodated in the vacuum chamber and comprising a hole, a gas supply portion configured to supply an inactive gas to the sub-chamber, and an irradiation source configured to apply vacuum ultraviolet rays or X-rays for ionizing the inactive gas supplied to inside of the sub-chamber.

The embodiments can provide a manufacturing device of a display device such that the reduction in reliability and yield can be prevented.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. When various elements are viewed parallel to the third direction Z, the appearance is defined as a plan view. When terms indicating the positional relationships of two or more structural elements, such as “on”, “above” “between” and “face”, are used, the target structural elements may be directly in contact with each other or may be spaced apart from each other as a gap or another structural element is interposed between them. The positive direction of the Z-axis is referred to as “on” or “above”.

The display device of the present embodiment is an organic electroluminescent display device comprising an organic light emitting diode (OLED) as a display element, and could be mounted on a television, a personal computer, a vehicle-mounted device, a tablet, a smartphone, a mobile phone, etc.

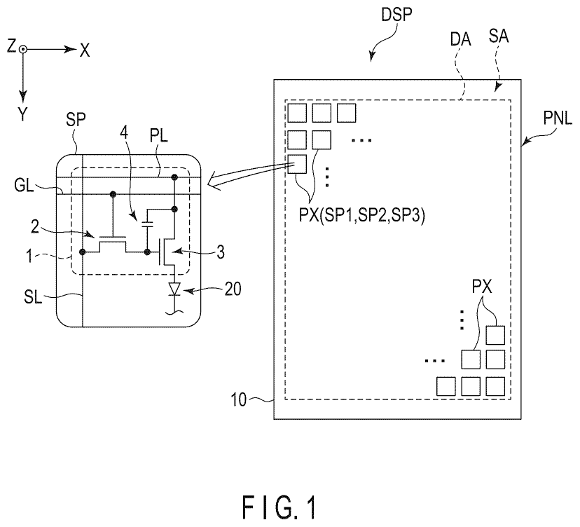

FIG. 1 is a diagram showing a configuration example of a display device DSP.

The display device DSP comprises a display panel PNL comprising a display area DA which displays an image and a surrounding area SA located on an external side relative to the display area DA on an insulating substrate 10. The substrate 10 may be glass or a resinous film having flexibility.

In the embodiment, the substrate 10 is rectangular as seen in plan view. It should be noted that the shape of the substrate 10 in plan view is not limited to a rectangle and may be another shape such as a square, a circle or an oval.

The display area DA comprises a plurality of pixels PX arrayed in matrix in a first direction X and a second direction Y. Each pixel PX includes a plurality of subpixels SP. For example, each pixel PX includes subpixel SP1 which exhibits a first color, subpixel SP2 which exhibits a second color and subpixel SP3 which exhibits a third color. The first color, the second color and the third color are different colors. Each pixel PX may include a subpixel SP which exhibits another color such as white in addition to subpixels SP1, SP2 and SP3 or instead of one of subpixels SP1, SP2 and SP3. It should be noted that the combination of subpixels is not limited to three elements. The combination may consist of two elements or may consist of four or more elements by adding subpixel SP4, etc., to subpixels SP1 to SP3.

Each subpixel SP comprises a pixel circuit 1 and a display element 20 driven by the pixel circuit 1. The pixel circuit 1 comprises a pixel switch 2, a drive transistor 3 and a capacitor 4. The pixel switch 2 and the drive transistor 3 are, for example, switching elements consisting of thin-film transistors.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the anode of the display element 20.

It should be noted that the configuration of the pixel circuit 1 is not limited to the example shown in the figure. For example, the pixel circuit 1 may comprise more thin-film transistors and capacitors.

The display element 20 is an organic light emitting diode (OLED) as a light emitting element, and may be called an organic EL element.

Although not described in detail, the surrounding area SA comprises a plurality of terminals for connecting an IC chip and a flexible printed circuit.

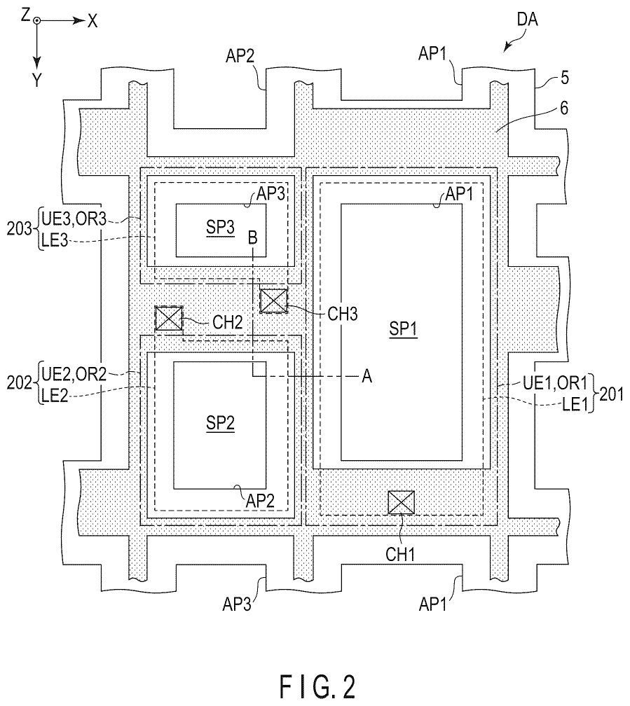

FIG. 2 is a diagram showing an example of the layout of subpixels SP1, SP2 and SP3.

In the example of FIG. 2, subpixels SP2 and SP3 are arranged in the second direction Y. Subpixels SP1 and SP2 are arranged in the first direction X, and subpixels SP1 and SP3 are arranged in the first direction X.

When subpixels SP1, SP2 and SP3 are provided in line with this layout, in the display area DA, a column in which subpixels SP2 and SP3 are alternately provided in the second direction Y and a column in which a plurality of subpixels SP1 are provided in the second direction Y are formed. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

A rib 5 and a partition 6 are provided in the display area DA. The rib 5 comprises apertures AP1, AP2 and AP3 in subpixels SP1, SP2 and SP3, respectively.

The partition 6 overlaps the rib 5 as seen in plan view. The partition 6 is formed into a grating shape surrounding the apertures AP1, AP2 and AP3. In other words, the partition 6 comprises apertures in subpixels SP1, SP2 and SP3 in a manner similar to that of the rib 5.

Subpixels SP1, SP2 and SP3 comprise display elements 201, 202 and 203, respectively, as the display elements 20.

The display element 201 of subpixel SP1 comprises a lower electrode LE1, an upper electrode UE1 and an organic layer OR1 overlapping the aperture AP1. The peripheral portion of the lower electrode LE1 is covered with the rib 5. The display element 201 comprising the lower electrode LE1, the organic layer OR1 and the upper electrode UE1 is surrounded by the partition 6 as seen in plan view. The peripheral portion of each of the organic layer OR1 and the upper electrode UE1 overlaps the rib 5 as seen in plan view. The organic layer OR1 includes a light emitting layer which emits light in, for example, a blue wavelength range.

The display element 202 of subpixel SP2 comprises a lower electrode LE2, an upper electrode UE2 and an organic layer OR2 overlapping the aperture AP2. The peripheral portion of the lower electrode LE2 is covered with the rib 5. The display element 202 comprising the lower electrode LE2, the organic layer OR2 and the upper electrode UE2 is surrounded by the partition 6 as seen in plan view. The peripheral portion of each of the organic layer OR2 and the upper electrode UE2 overlaps the rib 5 as seen in plan view. The organic layer OR2 includes a light emitting layer which emits light in, for example, a green wavelength range.

The display element 203 of subpixel SP3 comprises a lower electrode LE3, an upper electrode UE3 and an organic layer OR3 overlapping the aperture AP3. The peripheral portion of the lower electrode LE3 is covered with the rib 5. The display element 203 comprising the lower electrode LE3, the organic layer OR3 and the upper electrode UE3 is surrounded by the partition 6 as seen in plan view. The peripheral portion of each of the organic layer OR3 and the upper electrode UE3 overlaps the rib 5 as seen in plan view. The organic layer OR3 includes a light emitting layer which emits light in, for example, a red wavelength range.

In the example of FIG. 2, the outer shapes of the lower electrodes LE1, LE2 and LE3 are shown by dotted lines, and the outer shapes of the organic layers OR1, OR2 and OR3 and the upper electrodes UE1, UE2 and UE3 are shown by alternate long and short dash lines. It should be noted that the outer shape of each of the lower electrodes, organic layers and upper electrodes shown in the figure does not necessarily reflect the accurate shape.

The lower electrodes LE1, LE2 and LE3 correspond to, for example, the anodes of the display elements. The upper electrodes UE1, UE2 and UE3 correspond to the cathodes of the display elements or a common electrode.

The lower electrode LE1 is connected to the pixel circuit 1 (see FIG. 1) of subpixel SP1 through a contact hole CH1. The lower electrode LE2 is connected to the pixel circuit 1 of subpixel SP2 through a contact hole CH2. The lower electrode LE3 is connected to the pixel circuit 1 of subpixel SP3 through a contact hole CH3.

In the example of FIG. 2, the area of the aperture AP1, the area of the aperture AP2 and the area of the aperture AP3 are different from each other. The area of the aperture AP1 is greater than that of the aperture AP2, and the area of the aperture AP2 is greater than that of the aperture AP3. In other words, the area of the lower electrode LE1 exposed from the aperture AP1 is greater than that of the lower electrode LE2 exposed from the aperture AP2. The area of the lower electrode LE2 exposed from the aperture AP2 is greater than that of the lower electrode LE3 exposed from the aperture AP3.

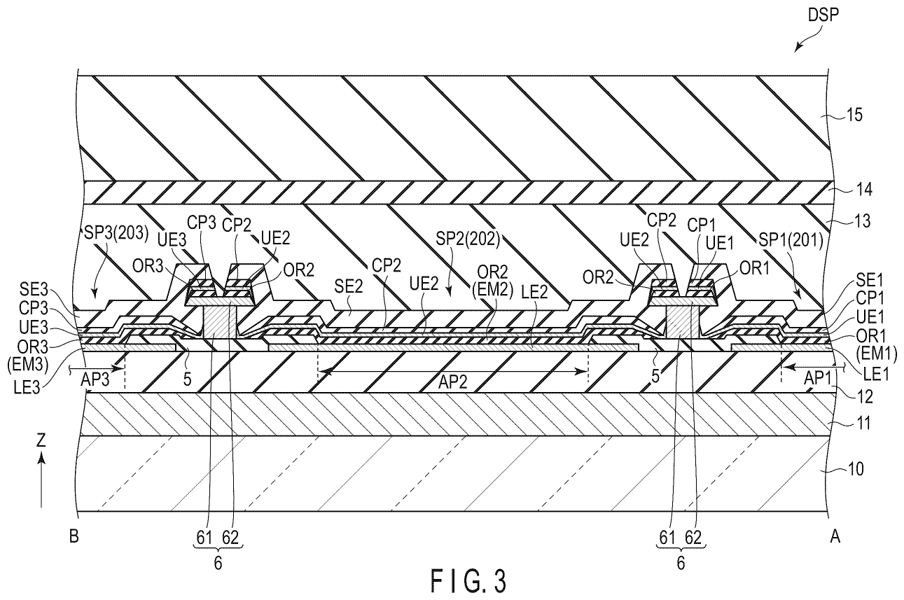

FIG. 3 is a schematic cross-sectional view of the display device DSP along the A-B line of FIG. 2.

A circuit layer 11 is provided on the substrate 10. The circuit layer 11 includes various circuits such as the pixel circuit 1 shown in FIG. 1 and various lines such as the scanning line GL, the signal line SL and the power line PL. The circuit layer 11 is covered with an insulating layer 12. The insulating layer 12 is an organic insulating layer which planarizes the irregularities formed by the circuit layer 11.

The lower electrodes LE1, LE2 and LE3 are provided on the insulating layer 12 and are spaced apart from each other. The rib 5 is provided on the insulating layer 12 and the lower electrodes LE1, LE2 and LE3. The aperture AP1 of the rib 5 overlaps the lower electrode LE1. The aperture AP2 overlaps the lower electrode LE2. The aperture AP3 overlaps the lower electrode LE3. The peripheral portions of the lower electrodes LE1, LE2 and LE3 are covered with the rib 5. Between, of the lower electrodes LE1, LE2 and LE3, the lower electrodes which are adjacent to each other, the insulating layer 12 is covered with the rib 5. The lower electrodes LE1, LE2 and LE3 are connected to the pixel circuits 1 of subpixels SP1, SP2 and SP3, respectively, through the contact holes provided in the insulating layer 12. It should be noted that, although the contact holes of the insulating layer 12 are omitted in FIG. 3, the contact holes correspond to the contact holes CH1, CH2 and HC3 of FIG. 2.

The partition 6 includes a conductive lower portion (stem) 61 provided on the rib 5 and an upper portion (shade) 62 provided on the lower portion 61. The lower portion 61 of the partition 6 shown on the right side of the figure is located between the aperture AP1 and the aperture AP2. The lower portion 61 of the partition 6 shown on the left side of the figure is located between the aperture AP2 and the aperture AP3. The upper portion 62 has a width greater than that of the lower portion 61. The both end portions of the upper portion 62 protrude relative to the side surfaces of the lower portion 61. This shape of the partition 6 is called an overhang shape.

The organic layer OR1 is in contact with the lower electrode LE1 through the aperture AP1 and covers the lower electrode LE1 exposed from the aperture AP1. The peripheral portion of the organic layer OR1 is located on the rib 5. The upper electrode UE1 covers the organic layer OR1 and is in contact with the lower portion 61.

The organic layer OR2 is in contact with the lower electrode LE2 through the aperture AP2 and covers the lower electrode LE2 exposed from the aperture AP2. The peripheral portion of the organic layer OR2 is located on the rib 5. The upper electrode UE2 covers the organic layer OR2 and is in contact with the lower portion 61.

The organic layer OR3 is in contact with the lower electrode LE3 through the aperture AP3 and covers the lower electrode LE3 exposed from the aperture AP3. The peripheral portion of the organic layer OR3 is located on the rib 5. The upper electrode UE3 covers the organic layer OR3 and is in contact with the lower portion 61.

In the example of FIG. 3, subpixel SP1 comprises a cap layer CP1 and a sealing layer SE1. Subpixel SP2 comprises a cap layer CP2 and a sealing layer SE2. Subpixel SP3 comprises a cap layer CP3 and a sealing layer SE3. The cap layers CP1, CP2 and CP3 function as optical adjustment layers which improve the extraction efficiency of the light emitted from the organic layers OR1, OR2 and OR3, respectively.

The cap layer CP1 is provided on the upper electrode UE1.

The cap layer CP2 is provided on the upper electrode UE2.

The cap layer CP3 is provided on the upper electrode UE3.

The sealing layer SE1 is provided on the cap layer CP1, is in contact with the partition 6 and continuously covers the members of subpixel SP1.

The sealing layer SE2 is provided on the cap layer CP2, is in contact with the partition 6 and continuously covers the members of subpixel SP2.

The sealing layer SE3 is provided on the cap layer CP3, is in contact with the partition 6 and continuously covers the members of subpixel SP3.

In the example of FIG. 3, each of the organic layer OR1, the upper electrode UE1 and the cap layer CP1 is partly located on the partition 6 around subpixel SP1. These portions are spaced apart from, of the organic layer OR1, the upper electrode UE1 and the cap layer CP1, the portions located in the aperture AP1 (the portions constituting the display element 201).

Similarly, each of the organic layer OR2, the upper electrode UE2 and the cap layer CP2 is partly located on the partition 6 around subpixel SP2. These portions are spaced apart from, of the organic layer OR2, the upper electrode UE2 and the cap layer CP2, the portions located in the aperture AP2 (the portions constituting the display element 202).

Similarly, each of the organic layer OR3, the upper electrode UE3 and the cap layer CP3 is partly located on the partition 6 around subpixel SP3. These portions are spaced apart from, of the organic layer OR3, the upper electrode UE3 and the cap layer CP3, the portions located in the aperture AP3 (the portions constituting the display element 203).

The end portions of the sealing layers SE1, SE2 and SE3 are located above the partition 6. In the example of FIG. 3, the end portions of the sealing layers SE1 and SE2 located above the partition 6 between subpixels SP1 and SP2 are spaced apart from each other. The end portions of the sealing layers SE2 and SE3 located above the partition 6 between subpixels SP2 and SP3 are spaced apart from each other.

The sealing layers SE1, SE2 and SE3 are covered with a resin layer 13. The resin layer 13 is covered with a sealing layer 14. The sealing layer 14 is covered with a resin layer 15.

Each of the rib 5, the sealing layers SE1, SE2 and SE3 and the sealing layer 14 is formed of an inorganic insulating material such as silicon nitride (SiNx), silicon oxide (Siox), silicon oxynitride (SiON) or aluminum oxide (Al₂O₃).

The lower portion 61 of the partition 6 is formed of a conductive material and is electrically connected to the upper electrodes UE1, UE2 and UE3. The upper portion 62 of the partition 6 is formed of, for example, a conductive material. However, the upper portion 62 may be formed of an insulating material. The lower portion 61 is formed of a material which is different from that of the upper portion 62.

For example, each of the lower electrodes LE1, LE2 and LE3 is a multilayer body including a transparent electrode formed of an oxide conductive material such as indium tin oxide (ITO) and a metal electrode formed of a metal material such as silver.

The organic layer OR1 includes a light emitting layer EM1. The organic layer OR2 includes a light emitting layer EM2. The organic layer OR3 includes a light emitting layer EM3. The light emitting layer EM1, the light emitting layer EM2 and the light emitting layer EM3 are formed of materials which are different from each other. For example, the light emitting layer EM1 is formed of a material which emits light in a blue wavelength range. The light emitting layer EM2 is formed of a material which emits light in a green wavelength range. The light emitting layer EM3 is formed of a material which emits light in a red wavelength range.

Each of the organic layers OR1, OR2 and OR3 includes a plurality of functional layers such as a hole injection layer, a hole transport layer, an electron blocking layer, a hole blocking layer, an electron transport layer and an electron injection layer.

Each of the upper electrodes UE1, UE2 and UE3 is formed of, for example, a metal material such as an alloy of magnesium and silver (MgAg).

Each of the cap layers CP1, CP2 and CP3 is a multilayer body consisting of a plurality of thin films. All of the thin films are transparent and have refractive indices different from each other. It should be noted that at least one of the cap layers CP1, CP2 and CP3 may be omitted.

Now, this specification explains a configuration example of a display element 20.

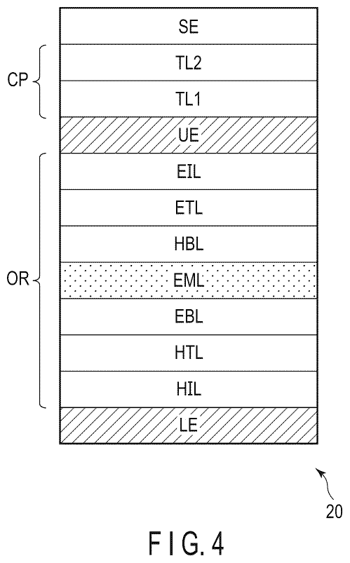

FIG. 4 is a diagram showing a configuration example of a display element 20.

The display element 20 shown in FIG. 4 could correspond to any one of the display elements 201, 202 and 203 described above.

Here, this specification explains an example in which a lower electrode LE corresponds to an anode and an upper electrode UE corresponds to a cathode.

The display element 20 comprises an organic layer OR (OR1, OR2 or OR3) between a lower electrode LE (LE1, LE2 or LE3) and an upper electrode UE (UE1, UE2 or UE3).

In the organic layer OR, a hole injection layer HIL, a hole transport layer HTL, an electron blocking layer EBL, a light emitting layer EML, a hole blocking layer HBL, an electron transport layer ETL and an electron injection layer EIL are stacked in this order.

It should be noted that the organic layer OR may include, in addition to the functional layers described above, other functional layers such as a carrier generation layer as needed, or at least one of the above functional layers may be omitted.

The light emitting layer EML corresponds to one of the light emitting layers EM1, EM2 and EM3 shown in FIG. 3.

A cap layer CP (CP1, CP2 or CP3) includes a first transparent layer TL1 and a second transparent layer TL2. The first transparent layer TL1 is provided on the upper electrode UE. The first transparent layer TL1 is a high-refractive layer having a refractive index which is higher than that of the upper electrode UE. The second transparent layer TL2 is provided on the first transparent layer TL1. The second transparent layer TL2 is a low-refractive layer having a refractive index which is less than that of the first transparent layer TL1. A sealing layer SE (SE1, SE2 or SE3) is provided on the second transparent layer TL2.

It should be noted that the configuration of the organic layer OR is not limited to the configuration of the figure in which the organic layer OR comprises the single light emitting layer EML. The organic layer OR may comprise a plurality of light emitting layers.

Now, this specification explains a manufacturing device 100 for forming the organic layer OR, upper electrode UE and cap layer CP shown in FIG. 4.

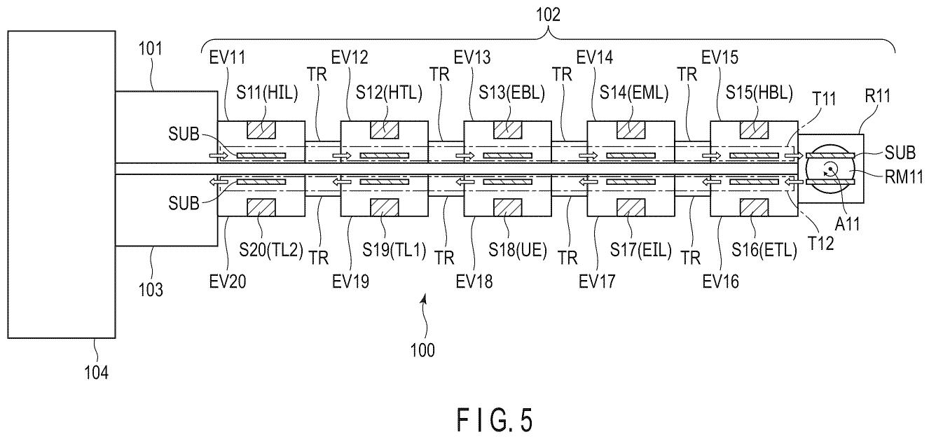

FIG. 5 is a diagram showing a configuration example of the manufacturing device 100.

The manufacturing device 100 is applied in, for example, the process of successively forming the organic layer OR, the upper electrode UE and the cap layer CP. A processing substrate SUB which is supposed to be carried in the manufacturing device 100 comprises the circuit layer 11, the insulating layer 12, the lower electrodes LE1, LE2 and LE3, the rib 5 and the partition 6 on the substrate 10.

The manufacturing device 100 comprises a preprocessing portion 101, an evaporation portion 102, a post-processing portion 103 and a substrate compartment 104.

The preprocessing portion 101 comprises a mechanism which performs various preprocesses for a processing substrate SUB which was carried in, such as a cleaning process, a drying process and a plasma process. The preprocessing portion 101 comprises a mechanism which sets the processing substrate SUB so as to be in a predetermined conveyance position, a mechanism which secures the processing substrate SUB to a dedicated carrier by an electrostatic chuck, etc. Each conveyance path of the evaporation portion 102 is configured to convey the carrier.

The post-processing portion 103 comprises a mechanism which releases the securing applied by the electrostatic chuck and removes the processing substrate SUB from the carrier, a mechanism which sets the processing substrate SUB so as to be in a predetermined position, etc.

A plurality of processing substrates SUB are accommodated in the substrate compartment 104. The preprocessing portion 101 and the post-processing portion 103 are connected to the substrate compartment 104. A processing substrates SUB in which lower electrodes, a partition and the like are formed is carried in the substrate compartment 104 from another processing portion. Further, the processing substrate SUB is carries out of the substrate compartment 104 into the preprocessing portion 101. The processing substrate SUB is carried out of the post-processing portion 103 into the substrate compartment 104. For example, the position of the processing substrate SUB accommodated in the substrate compartment 104 is a horizontal position. The conveyance position of the processing substrate SUB which is conveyed through the evaporation portion 102 is a perpendicular position.

The evaporation portion 102 comprises a plurality of evaporation chambers EV11 to EV20, a rotation chamber R11 and a plurality of conveyance chambers TR. The preprocessing portion 101, the post-processing portion 103, the substrate compartment 104, the evaporation chambers EV11 to EV20, the rotation chamber R11 and the conveyance chambers TR are connected to each other and are maintained as a high vacuum. For example, the pressure of each portion is maintained so as to be less than 10⁻³ Pa. Further, in some cases, the pressure could be maintained so as to be approximately 10⁻⁵ Pa.

The evaporation chambers EV11 to EV15 are arranged in line. The evaporation chamber EV11 is connected to the preprocessing portion 101. The evaporation chamber EV15 is connected to the rotation chamber R11. A plurality of conveyance chambers TR are provided between the evaporation chamber EV11 and the evaporation chamber EV12, between the evaporation chamber EV12 and the evaporation chamber EV13, between the evaporation chamber EV13 and the evaporation chamber EV14 and between the evaporation chamber EV14 and the evaporation chamber EV15, respectively, such that the two evaporation chambers are connected to each other by a corresponding conveyance chamber TR. A conveyance path T11 is provided over the evaporation chambers EV11 to EV15 and the conveyance chambers TR.

The evaporation chambers EV16 to EV20 are arranged in line. The evaporation chamber EV20 is connected to the post-processing portion 103. The evaporation chamber EV16 is connected to the rotation chamber R11. A plurality of conveyance chambers TR are provided between the evaporation chamber EV16 and the evaporation chamber EV17, between the evaporation chamber EV17 and the evaporation chamber EV18, between the evaporation chamber EV18 and the evaporation chamber EV19 and between the evaporation chamber EV19 and the evaporation chamber EV20, respectively, such that the two evaporation chambers are connected to each other by a corresponding conveyance chamber TR. A conveyance path T12 is provided over the evaporation chambers EV16 to EV20 and the conveyance chambers TR.

The evaporation chamber EV11 comprises an evaporation source S11. The evaporation source S11 is configured to emit a material for forming a hole injection layer HIL toward the conveyance path T11.

The evaporation chamber EV12 comprises an evaporation source S12. The evaporation source S12 is configured to emit a material for forming a hole transport layer HTL toward the conveyance path T11.

The evaporation chamber EV13 comprises an evaporation source S13. The evaporation source S13 is configured to emit a material for forming an electron blocking layer EBL toward the conveyance path T11.

The evaporation chamber EV14 comprises an evaporation source S14. The evaporation source S14 is configured to emit a material for forming a light emitting layer EML toward the conveyance path T11.

The evaporation chamber EV15 comprises an evaporation source S15. The evaporation source S15 is configured to emit a material for forming a hole blocking layer HBL toward the conveyance path T11.

The evaporation chamber EV16 comprises an evaporation source S16. The evaporation source S16 is configured to emit a material for forming an electron transport layer ETL toward the conveyance path T12.

The evaporation chamber EV17 comprises an evaporation source S17. The evaporation source S17 is configured to emit a material for forming an electron injection layer EIL toward the conveyance path T12.

The evaporation chamber EV18 comprises an evaporation source S18. The evaporation source S18 is configured to emit a material for forming an upper electrode UE toward the conveyance path T12.

The evaporation chamber EV19 comprises an evaporation source S19. The evaporation source S19 is configured to emit a material for forming a first transparent layer TL1 toward the conveyance path T12.

The evaporation chamber EV20 comprises an evaporation source S20. The evaporation source S20 is configured to emit a material for forming a second transparent layer TL2 toward the conveyance path T12.

The conveyance path T11 and the conveyance path T12 are provided inside the evaporation portion 102. The evaporation sources S11 to S20 are provided outside the conveyance path T11 and the conveyance path T12 in the evaporation portion 102. For example, when the evaporation chambers EV11 and EV20 are particularly looked at, the conveyance paths T11 and T12 are located between the evaporation source S11 and the evaporation source S20. When the evaporation chambers EV15 and EV16 are particularly looked at, the conveyance paths T11 and T12 are located between the evaporation source S15 and the evaporation source S16.

The rotation chamber R11 is configured to convey the processing substrate SUB which is carried out of the conveyance path T11 to the conveyance path T12. The rotation chamber R11 comprises a rotation mechanism RM11. The rotation mechanism RM11 is configured to hold the processing substrate SUB which is carried in the rotation chamber R11 via the conveyance path T11 and rotate around a rotation axis A11.

This specification hereinafter explains the manufacturing process in the manufacturing device 100.

First, a processing substrate SUB in which a lower electrode LE is formed is carried out of the substrate compartment 104 and carried in the preprocessing portion 101. In the preprocessing portion 101, a predetermined preprocess is performed for the processing substrate SUB.

Subsequently, the processing substrate SUB is carried in the evaporation chamber EV11. In the evaporation chamber EV11, the material emitted from the evaporation source S11 is deposited on the processing substrate SUB which is conveyed through the conveyance path T11. By this process, a hole injection layer HIL is formed on the lower electrode LE.

Subsequently, the processing substrate SUB passes through the conveyance chamber TR and is carried in the evaporation chamber EV12. In the evaporation chamber EV12, the material emitted from the evaporation source S12 is deposited on the processing substrate SUB which is conveyed through the conveyance path T11. By this process, a hole transport layer HTL is formed on the hole injection layer HIL.

Subsequently, the processing substrate SUB passes through the conveyance chamber TR and is carried in the evaporation chamber EV13. In the evaporation chamber EV13, the material emitted from the evaporation source S13 is deposited on the processing substrate SUB which is conveyed through the conveyance path T11. By this process, an electron blocking layer EBL is formed on the hole transport layer HTL.

Subsequently, the processing substrate SUB passes through the conveyance chamber TR and is carried in the evaporation chamber EV14. In the evaporation chamber EV14, the material emitted from the evaporation source S14 is deposited on the processing substrate SUB which is conveyed through the conveyance path T11. By this process, a light emitting layer EML is formed on the electron blocking layer EBL.

Subsequently, the processing substrate SUB passes through the conveyance chamber TR and is carried in the evaporation chamber EV15. In the evaporation chamber EV15, the material emitted from the evaporation source S15 is deposited on the processing substrate SUB which is conveyed through the conveyance path T11. By this process, a hole blocking layer HBL is formed on the light emitting layer EML.

Subsequently, the processing substrate SUB is carried in the rotation chamber R11. In the rotation chamber R11, the rotation mechanism RM11 holds the processing substrate SUB which was carried in. The rotation mechanism RM11 rotates 180° while holding the processing substrate SUB.

Subsequently, the processing substrate SUB is carried in the evaporation chamber EV16. In the evaporation chamber EV16, the material emitted from the evaporation source S16 is deposited on the processing substrate SUB which is conveyed through the conveyance path T12. By this process, an electron transport layer ETL is formed on the hole blocking layer HBL.

Subsequently, the processing substrate SUB passes through the conveyance chamber TR and is carried in the evaporation chamber EV17. In the evaporation chamber EV17, the material emitted from the evaporation source S17 is deposited on the processing substrate SUB which is conveyed through the conveyance path T12. By this process, an electron injection layer EIL is formed on the electron transport layer ETL.

Subsequently, the processing substrate SUB passes through the conveyance chamber TR and is carried in the evaporation chamber EV18. In the evaporation chamber EV18, the material emitted from the evaporation source S18 is deposited on the processing substrate SUB which is conveyed through the conveyance path T12. By this process, an upper electrode UE is formed on the electron injection layer EIL.

Subsequently, the processing substrate SUB passes through the conveyance chamber TR and is carried in the evaporation chamber EV19. In the evaporation chamber EV19, the material emitted from the evaporation source S19 is deposited on the processing substrate SUB which is conveyed through the conveyance path T12. By this process, a first transparent layer TL1 is formed on the upper electrode UE.

Subsequently, the processing substrate SUB passes through the conveyance chamber TR and is carried in the evaporation chamber EV20. In the evaporation chamber EV20, the material emitted from the evaporation source S20 is deposited on the processing substrate SUB which is conveyed through the conveyance path T12. By this process, a second transparent layer TL2 is formed on the first transparent layer TL1.

Subsequently, the processing substrate SUB is carried in the post-processing portion 103. In the post-processing portion 103, a predetermined post-process is performed for the processing substrate SUB.

Subsequently, the processing substrate SUB is carried in the substrate compartment 104.

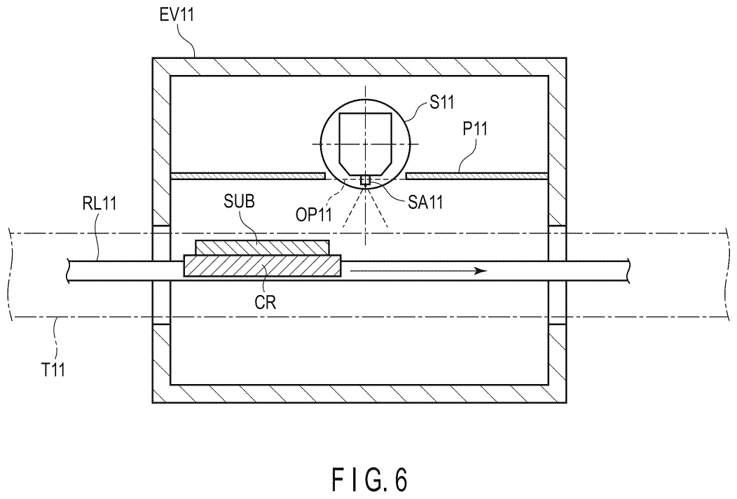

FIG. 6 is a cross-sectional view showing a configuration example of the typical evaporation chamber EV11.

In the evaporation chamber EV11, the evaporation source S11 faces the conveyance path T11 across the intervening opening OP11 of a partition plate P11. A rail RL11 is provided in the conveyance path T11. A carrier CR which holds a processing substrate SUB is configured to move along the rail RL11.

The evaporation source S11 is configured to apply heat to a material, vaporize the material and continuously emit the material during the operation of the manufacturing device 100. In a mode in which the emitted material is deposited on the processing substrate SUB, the evaporation source S11 is set such that a discharge port SA11 faces the conveyance path T11 (or the processing substrate SUB). In a mode in which the emitted material is not deposited on the processing substrate SUB, the evaporation source S11 is set such that the evaporation source S11 rotates 90° from the state shown in the figure and the discharge port SA11 faces the inner side surrounded by the partition plate P11.

Alternatively, although not shown in the figure, a shutter which can open and close may be provided in the opening OP11.

The other evaporation chambers EV12 to EV20 shown in FIG. 5 are configured in the same manner as the evaporation chamber EV11 shown in FIG. 6.

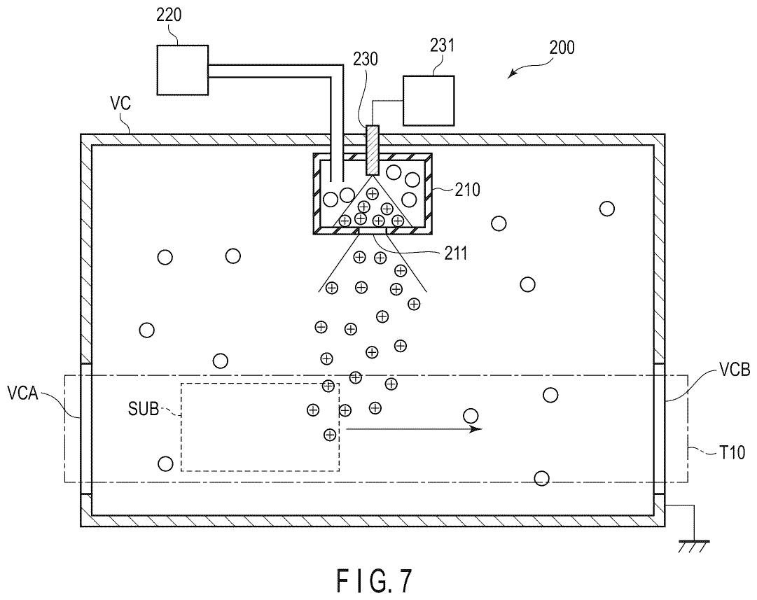

FIG. 7 is a diagram for explaining an ionizer 200 which can be applied to the manufacturing device 100 shown in FIG. 5.

The pressure of a vacuum chamber CV is maintained so as to be less than 10-3 Pa. The vacuum chamber VC is made from, for example, metal, and is grounded. The vacuum chamber VC comprises a carry-in entrance VCA for carrying a processing substrate SUB shown by dotted lines in and a carry-out exit VCB for carrying the processing substrate SUB out. A conveyance path T10 for conveying the processing substrate SUB is provided from the carry-in entrance VCA to the carry-out exit VCB inside the vacuum chamber VC.

The ionizer 200 is configured such that ions are generated inside the vacuum chamber VC. The ionizer 200 is provided on, for example, the top board of the vacuum chamber VC. However, it may be provided on the side boards or the bottom board.

This ionizer 200 comprises a sub-chamber 210, a gas supply portion 220 and an irradiation source 230.

The sub-chamber 210 is accommodated in the vacuum chamber VC. The sub-chamber 210 comprises a tiny hole 211. The sub-chamber 210 communicates with the vacuum chamber VC via the hole 211. Either a single hole 211 or a plurality of holes 211 may be provided. The diameter of the hole 211 is, for example, approximately 2 to 10 mm.

The sub-chamber 210 is electrically insulated from the vacuum chamber VC. For example, the sub-chamber 210 is formed of an insulating material such as a ceramic, glass or synthetic resinous material. As another example, the sub-chamber 210 is made from metal, and is connected to the vacuum chamber VC via an insulating material.

The gas supply portion 220 is configured to supply an inactive gas to the inside of the sub-chamber 210. The flow rate of the inactive gas supplied from the gas supply portion 220 is set to the extent that the degree of vacuum of the vacuum chamber VC is not decreased. For example, the flow rate of the inactive gas is set so as to be approximately 2 ml/min. For the inactive gas, for example, krypton, xenon, argon or nitrogen can be used. For the inactive gas, argon or nitrogen should be preferably applied since they are effectively ionized even in a high vacuum and further they are inexpensive.

The irradiation source 230 is an energy irradiation source for ionizing the inactive gas supplied to the inside of the sub-chamber 210. The irradiation source 230 is driven by a driver 231. For example, the irradiation source 230 is a light source configured to apply vacuum ultraviolet (VUV) rays. As another example, the irradiation source 230 is an X-ray source configured to apply X-rays or soft X-rays. When the irradiation source 230 applies vacuum ultraviolet rays or X-rays in a state where an inactive gas is supplied to the inside of the sub-chamber 210, the inactive gas is ionized.

In the sub-chamber 210, as ions, either cations or anions can be generated. These ions are used to remove static electricity from the processing substrate SUB which is conveyed inside the vacuum chamber VC.

The vacuum chamber VC maintained as a high vacuum has a small amount of gas inside the vacuum chamber VC. Thus, even if vacuum ultraviolet rays or X-rays are applied inside the vacuum chamber VC, ions are not sufficiently generated.

In the embodiment, when an inactive gas is supplied to the sub-chamber 210, and vacuum ultraviolet rays or X-rays are applied to the inactive gas in the sub-chamber 210, high-density ions can be generated inside the sub-chamber 210. The generated ions are applied from the hole 211 to the vacuum chamber VC.

In a case where the processing substrate SUB which is conveyed inside the vacuum chamber VC is undesirably electrically charged, the ions emitted from the sub-chamber 210 are attracted to the processing substrate SUB, and thus, the charge is neutralized (removed). This configuration prevents problems such as an electrostatic breakdown which is caused by undesired charge of the processing substrate SUB in the manufacturing process. Thus, the reduction in reliability and yield can be prevented.

To obtain sufficient time for removing static electricity, the ionizer 200 described above should be preferably provided in a vacuum chamber in which the conveyance time or residence time of the processing substrate SUB is relatively long.

To increase the ion density, the ionizer 200 described above should be preferably driven at all times while the manufacturing device 100 operates regardless of whether or not a processing substrate SUB which is conveyed is present.

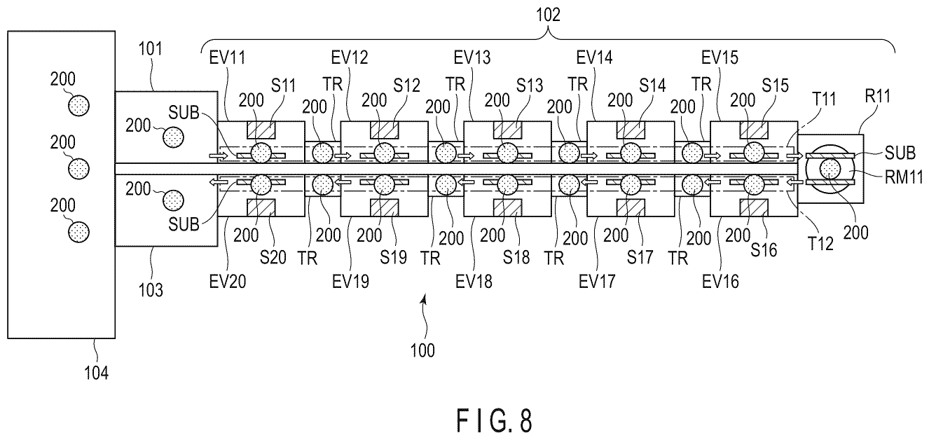

FIG. 8 is a diagram for explaining an installation example of the ionizer 200 in the manufacturing device 100 shown in FIG. 5.

The ionizer 200 can be provided in any one of the preprocessing portion 101, the evaporation portion 102, the post-processing portion 103 and the substrate compartment 104. In the evaporation portion 102, the ionizer 200 can be provided in any one of the evaporation chambers EV11 to EV20, the conveyance chambers TR and the rotation chamber R11.

For example, in a case where the ionizer 200 is provided in the evaporation chamber EV11, the vacuum chamber VC shown in FIG. 7 corresponds to the evaporation chamber EV11, and the conveyance path T10 corresponds to the conveyance path T11. In this case, the evaporation chamber VC shown in FIG. 7 further comprises the evaporation source S11 in addition to the ionizer 200. It should be noted that, in a case where the ionizer 200 is provided in the evaporation chambers EV11 to EV20, the type and flow rate of the inactive gas are set such that the generated ions do not adversely affect vapor deposition.

For example, in a case where the ionizer 200 is provided in the rotation chamber R11, the vacuum chamber VC shown in FIG. 7 corresponds to the rotation chamber R11, and the rotation mechanism RM11 is provided in the conveyance path T10. As the vapor deposition of materials is not performed in the rotation chamber R11, the type of the inactive gas can be selected from a wide range. Further, since the rotation mechanism RM11 rotates while holding the processing substrate SUB, the residence time of the processing substrate SUB in the rotation chamber R11 is relatively long, thereby allowing sufficient time for removing static electricity.

In a case where the ionizer 200 is provided in the substrate compartment 104, the residence time of the processing substrate SUB is long, and thus, sufficient time for removing static electricity can be obtained.

As described above, the embodiments can provide a manufacturing device of a display device such that the reduction in reliability and yield can be prevented.

All of the manufacturing devices that can be implemented by a person of ordinary skill in the art through arbitrary design changes to the manufacturing device described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A manufacturing device of a display device, comprising:
a vacuum chamber;
a conveyance path provided inside the vacuum chamber and provided for conveying a processing substrate for the display device; and
an ionizer configured to generate ions inside the vacuum chamber, wherein
the ionizer comprises:
a sub-chamber accommodated in the vacuum chamber and comprising a hole;
a gas supply portion configured to supply an inactive gas to the sub-chamber; and
an irradiation source configured to apply vacuum ultraviolet rays or X-rays for ionizing the inactive gas supplied to inside of the sub-chamber.

2. The manufacturing device of claim 1, wherein
a pressure of the vacuum chamber is maintained so as to be less than 10-3 Pa.

3. The manufacturing device of claim 1, wherein
the vacuum chamber is grounded, and
the sub-chamber is electrically insulated from the vacuum chamber.

4. The manufacturing device of claim 1, wherein
the sub-chamber is formed of an insulating material.

5. The manufacturing device of claim 1, wherein
the gas supply portion is configured to supply nitrogen or argon as the inactive gas.

6. The manufacturing device of claim 1, further comprising an evaporation source accommodated in the vacuum chamber, wherein
the evaporation source is configured to emit a material toward a conveyance path for conveying the processing substrate in which a lower electrode is formed.

7. The manufacturing device of claim 6, wherein
the material emitted from the evaporation source is a material for forming one of an organic layer, an upper electrode and a cap layer.

8. The manufacturing device of claim 1, further comprising a rotation mechanism accommodated in the vacuum chamber, wherein
the rotation mechanism is configured to rotate while holding the processing substrate.

9. A manufacturing device of a display device, comprising:
a substrate compartment which accommodates a processing substrate for the display device in which a lower electrode is formed;
a preprocessing portion which performs a preprocess for the processing substrate;
an evaporation chamber comprising an evaporation source configured to emit a material for forming one of an organic layer, an upper electrode and a cap layer toward the processing substrate;
a conveyance chamber in which the processing substrate is conveyed;
a rotation chamber comprising a rotation mechanism configured to rotate while holding the processing substrate;
a post-processing portion which performs a post-process for the processing substrate; and
an ionizer provided in at least one vacuum chamber of the substrate compartment, the preprocessing portion, the evaporation chamber, the conveyance chamber, the rotation chamber and the post-processing portion, and configured to generate ions inside the vacuum chamber, wherein
the ionizer comprises:
a sub-chamber accommodated in the vacuum chamber and comprising a hole;
a gas supply portion configured to supply an inactive gas to the sub-chamber; and
an irradiation source configured to apply vacuum ultraviolet rays or X-rays for ionizing the inactive gas supplied to inside of the sub-chamber.

10. The manufacturing device of claim 9, wherein
the substrate compartment, the preprocessing portion, the evaporation chamber, the conveyance chamber and the post-processing portion are connected to each other and are maintained so as to have a pressure less than 10-3 Pa.

11. The manufacturing device of claim 9, wherein
the vacuum chamber is grounded, and
the sub-chamber is electrically insulated from the vacuum chamber.

12. The manufacturing device of claim 9, wherein
the sub-chamber is formed of an insulating material.

13. The manufacturing device of claim 9, wherein
the gas supply portion is configured to supply nitrogen or argon as the inactive gas.

14. The manufacturing device of claim 9, wherein the evaporation chamber comprises the ionizer and the evaporation source.

15. The manufacturing device of claim 9, wherein the rotation chamber comprises the ionizer and the rotation mechanism.
